(19) United States
(12) Patent Application Publication
(10) Pub. No.: US 2008/0242042 A1
(43) Pub. Date: Oct. 2, 2008

(54) METHOD FOR FABRICATING A CAPACITOR IN A SEMICONDUCTOR DEVICE

(75) Inventors: Jong-Kuk KIM, Ichon-shi (KR); Jung-Seock Lee, Ichon-shi (KR); Phil-Goo Kong, Ichon-shi (KR); Hyun Ahn, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/771,753

(22) Filed: Jun. 29, 2007

(30) Foreign Application Priority Data
Mar. 29, 2007 (KR) 10-2007-0031074

(51) Int. Cl. H01L 21/02

(52) U.S. Cl. 438/397; 257/E21.011

(57) ABSTRACT

A method for fabricating a capacitor in a semiconductor device includes forming a sacrificial layer and a support layer on a substrate. A plurality of openings are formed by etching the support layer and the sacrificial layer. An electrode is formed in inner walls of the openings including sidewalls of the support layer patterned through etching. A portion of the patterned support layer is removed, and the sacrificial layer is also removed.

### CROSS-REFERENCE TO RELATED APPLICATIONS

The present invention claims priority to Korean patent application number 10-2007-0031074, filed on Mar. 29, 2007, which is incorporated by reference in its entirety.

### BACKGROUND OF THE INVENTION

The present invention relates to a method for fabricating a semiconductor device, and more particularly, to a method for fabricating a capacitor in a semiconductor device.

In a semiconductor device, as a minimum line-width decreases and integration increases, a region for forming a capacitor also decreases. Although the region for forming a capacitor decreases, a capacitor in a cell should acquire a high capacitance required for each cell. Accordingly, a method for fabricating a cylinder-shaped capacitor by removing a sacrificial layer between capacitors has been suggested.

FIGS. 1A and 1B illustrate a typical method for fabricating a capacitor in a semiconductor device. Referring to FIG. 1A, an oxide layer 102 and storage node contact plugs 103 penetrating the oxide layer 102 are formed over a semiconductor substrate 101. An etch barrier nitride layer 104 is formed over the resultant structure including the storage node contact plugs 103. A sacrificial oxide layer 105 is formed on the etch barrier nitride layer 104. Openings 106 above the storage node contact plugs 103 are formed by selectively etching the sacrificial oxide layer 105 and the etch barrier nitride layer 104.

A lower electrode 107 is formed by forming a conductive layer over the resultant structure including the openings 106 and performing an isolation process on the conductive layer. Referring to FIG. 1B, the sacrificial oxide layer 105 that forms the openings 106 is removed. The sacrificial oxide layer 105 may be removed through a dip-out treatment. As described above, the conventional method forms a cylinder-shaped capacitor by forming the lower electrode 107 and removing the sacrificial oxide layer 105 through the dip-out treatment in order to reduce shortage of the capacitance of a concave-type capacitor. However, in the conventional method, a bridge effect occurs between lower electrodes as the lower electrode 107 slants downward during the dip-out treatment of the sacrificial oxide layer 105. This result is because a bottom critical dimension (CD) of the lower electrode 107 decreases according to the high integration of a device and the lower electrode 107 is positioned at a higher level to increase capacitance.

### SUMMARY OF THE INVENTION

Embodiments of the present invention are directed toward providing a capacitor fabrication method that can reduce leaning and a bridge effect of a lower electrode during a dip-out treatment in a semiconductor device.

In accordance with an aspect of the present invention, a method for fabricating a capacitor in a semiconductor device, includes forming a sacrificial layer and a support layer on a substrate. A plurality of openings are formed by etching the support layer and the sacrificial layer. An electrode is formed in inner walls of a plurality of openings including sidewalls of the support layer patterned through etching. A portion of the patterned support layer is removed. The sacrificial layer is then removed.

In accordance with another aspect of the present invention, there is provided a method for fabricating a capacitor in a semiconductor device. The method includes forming a sacrificial layer and a support layer over a substrate, forming a plurality of openings by etching the support layer and the sacrificial layer, forming an electrode in inner walls of the openings, removing a portion of the support layer, and removing the sacrificial layer.

### BRIEF DESCRIPTION OF THE DRAWINGS

FIGS. 1A and 1B illustrate a conventional method for fabricating a capacitor in a semiconductor device.

FIG. 2 is a top view showing a capacitor of a semiconductor device in accordance with a first embodiment of the present invention.

FIGS. 3A to 3F illustrate a method for fabricating a capacitor of the semiconductor device in accordance with a second embodiment of the present invention.

FIG. 3G is a perspective view of the capacitor shown in FIG. 3F.

FIG. 4 illustrates a capacitor of the semiconductor device in accordance with a third embodiment of the present invention.

FIG. 5 illustrates a capacitor fabricating method of the semiconductor device in accordance with a fourth embodiment of the present invention

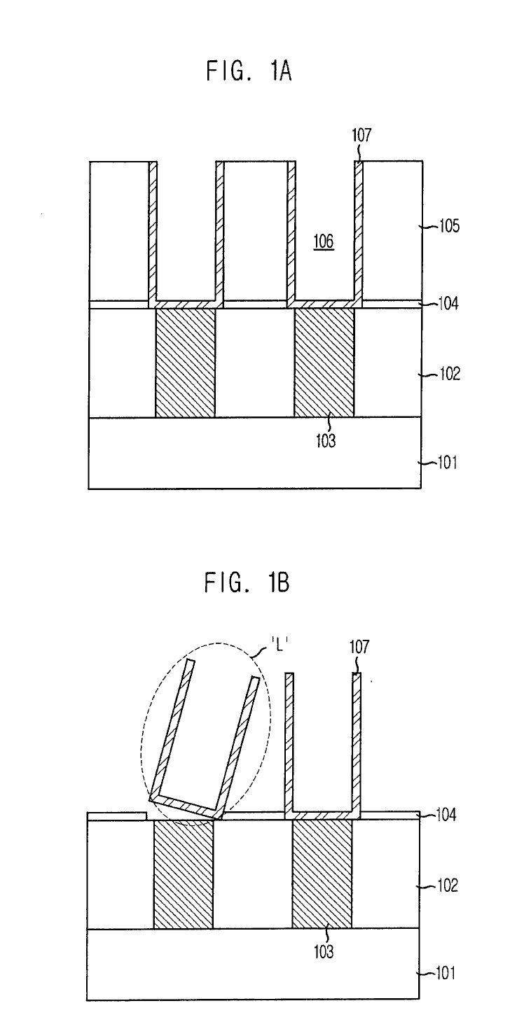

### DESCRIPTION OF SPECIFIC EMBODIMENTS

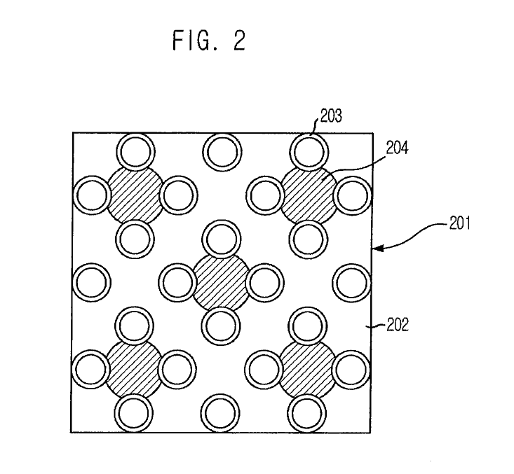

FIG. 2 is a top view showing a capacitor fabricating method of a semiconductor device in accordance with a first embodiment of the present invention. Referring to FIG. 2, a sacrificial layer 202 including a plurality of lower electrodes 203 is formed over a substrate 201. Subsequently, a support layer 204 connected in a diamond-shape to four neighboring lower electrodes 203 is formed. The support layer 204 may be a nitride layer.

As described above, leaning of the lower electrodes 203 and a bridge effect between the lower electrodes 203 are reduced in a subsequent dip-out treatment of the sacrificial layer 202 by forming the support layer 204 connected to the four neighboring lower electrodes 203 in a diamond shape. Since the lower electrode 203 having a small bottom critical dimension (CD) and a large height due to high integration of the semiconductor device is supported by the support layer 204, the leaning of the lower electrodes 203 is reduced in a subsequent dip-out treatment of the sacrificial layer 202. A method for forming the support layer 204 and the cylinder-shaped lower electrode will be described in detail hereinafter.

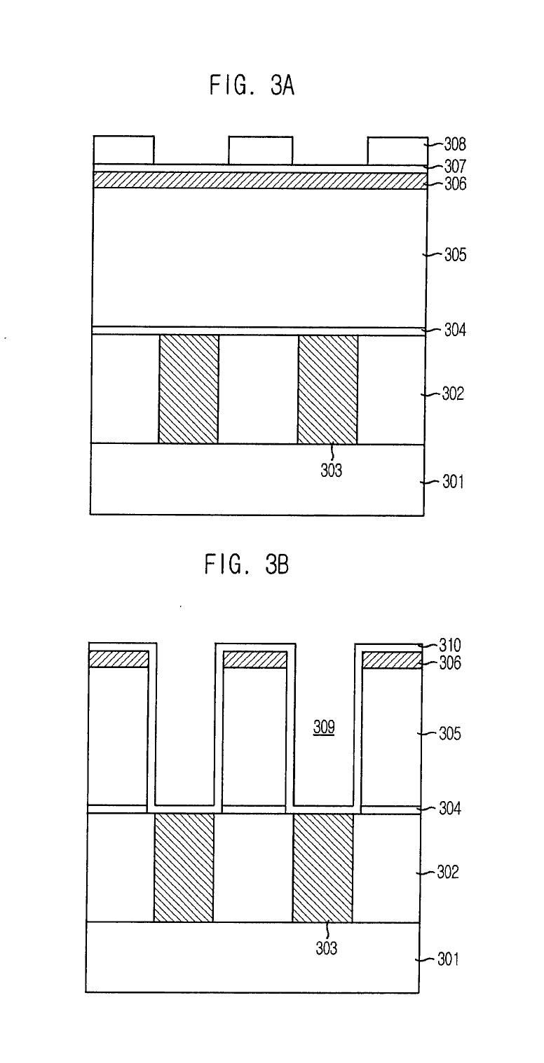

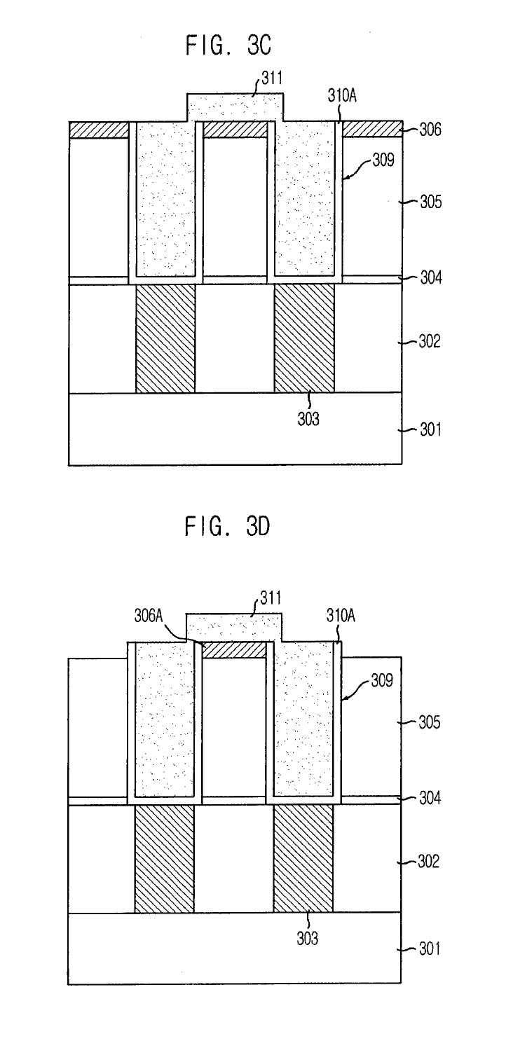

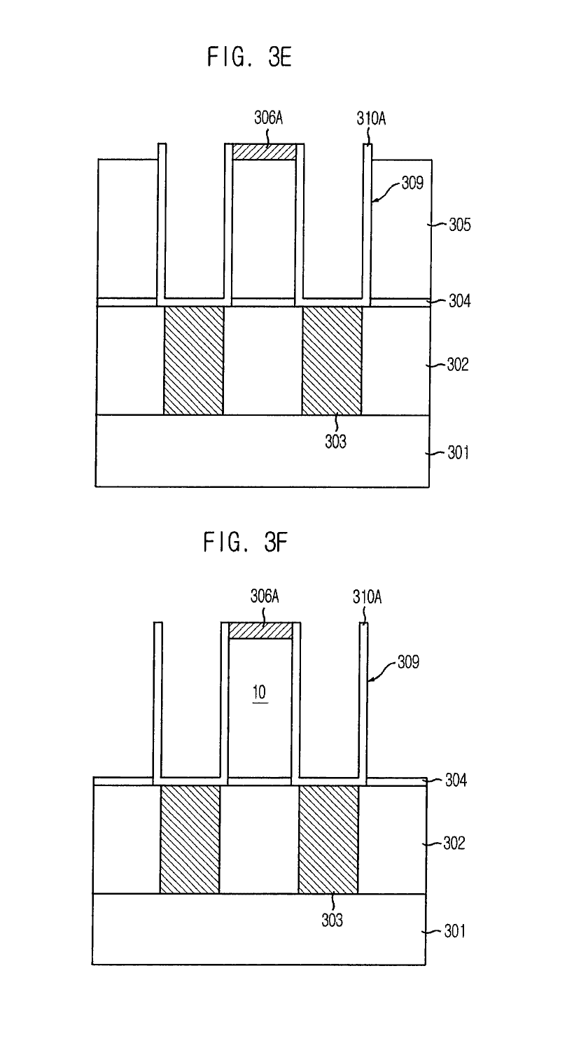

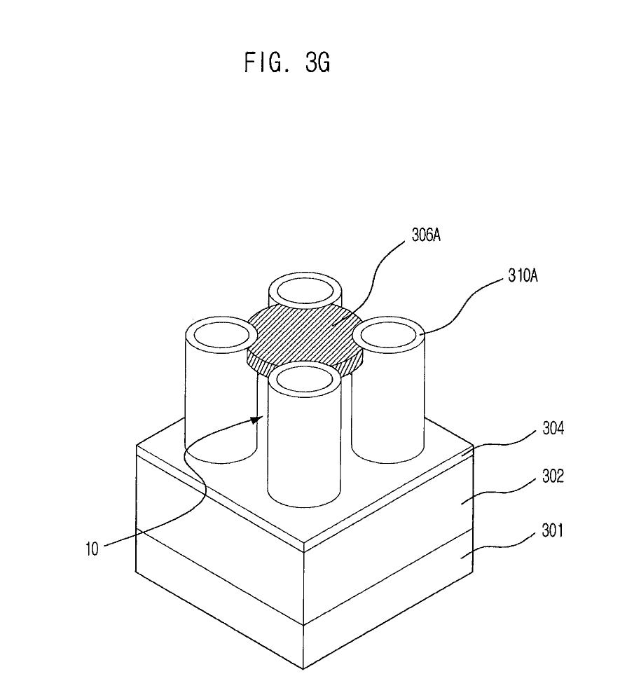

FIGS. 3A to 3F illustrate a method for fabricating a capacitor of the semiconductor device in accordance with a second embodiment of the present invention. FIG. 3G is a perspective view of the capacitor shown in FIG. 3F.

Referring to FIG. 3A, an insulation layer 302 is formed over a substrate 301. The substrate 301 may be a semiconductor substrate where a Dynamic Random Access Memory (DRAM) process is performed. The insulation layer 302 may be formed of a single layer or multiple layers. In one embodiment, the insulation layer 302 may be an oxide layer. A gate pattern and a bit line pattern may be formed before the insulation layer 302 is formed.

Storage node contact plugs 303 are formed to penetrate the insulation layer 302, and connected to the substrate 301. The storage node contact plugs 303 include a conductive material, e.g., polysilicon.

An etch barrier layer 304 is formed over a resultant structure including the storage node contact plugs 303. The etch barrier layer 304 protects a bottom layer from being damaged when subsequent openings are formed and the sacrificial layer is dipped out. The etch barrier layer 304 includes a material having an etching selectivity that may be the same as the insulation layer 302 and the sacrificial layer to be subsequently formed. For example, the etch barrier layer 304 may be a nitride layer.

A sacrificial layer 305 is formed over the etch barrier layer 304. The sacrificial layer 305 provides openings over which a subsequent lower electrode is formed. The sacrificial layer 305 is an oxide layer. A support layer 306 is formed over the sacrificial layer 305. The support layer 306 reduces leaning of the lower electrode in the subsequent dip-out treatment of the sacrificial layer 305. The support layer 306 has a thickness ranging from about 100 Å to 3000 Å and includes a material having an etching selectivity that may be the same as the sacrificial layer 305 and a subsequent lower electrode. For example, the support layer 306 may be a nitride layer.

An anti-reflective coating layer 307 is formed over the support layer 306. The anti-reflective coating layer 307 reduces reflection when a first photoresist layer pattern is formed. A first photoresist layer pattern 308 forms openings to expose the anti-reflective coating layer 307. The first photoresist layer pattern 308 is formed by coating the upper surface of the anti-reflective coating layer 307 with the photoresist layer and performing patterning to form the openings through a photolithography process.

Referring to FIG. 3B, openings 309 are formed by etching the anti-reflective coating layer 307, the support layer 306 and the sacrificial layer 305. The support layer 306 may be etched using a gas such as O₂ or Ar in addition to a fluorine-based gas. The fluorine-based gas may include CF₄, CHF₃, CH₂F₂, C₄F₆ or C₄F₈.

When the openings 309 are formed, both of the first photoresist layer pattern 308 and the anti-reflective coating layer 307 may be etched away or may be removed using oxygen after formation of the openings 309. Therefore, a structure with the openings 309 is a stacked structure including the sacrificial layer 305 and the support layer 306. A conductive layer 310 for a lower electrode is formed over the resultant structure including the openings 309.

Referring to FIG. 3C, a lower electrode 310A is formed by isolating the conductive layer 310 for the lower electrode. The lower electrode 310A may be isolated through an etch-back process. In the etch-back process, a cell open barrier etch-back is performed. Although the specific embodiment of the present invention illustrates only a cell region of the semiconductor substrate, the etch-back is performed after forming a cell open barrier mask on an adjacent region where the lower electrode is not formed to selectively open only the cell region in the etch-back process. Therefore, the lower electrode 310A is formed in inner walls of a plurality of openings 309 including sidewalls of the support layer 306 patterned by the etching process. A second photoresist layer pattern 311 is formed to remain in an upper portion of the support layer 306 and in an inside of the openings 309, which are both connected to a neighboring lower electrode 310A.

The second photoresist layer pattern 311 is formed by coating the resultant structure including the lower electrode 310A with the photoresist layer until the openings 309 are filled, and patterning the photoresist layer through photolithography such that the second photoresist layer pattern remains in the inside of the openings 309 and in the upper portion of the support layer 306 which is connected to the neighboring lower electrode 310A.

Referring to FIG. 3D, the opened support layer 306 is completely etched. The support layer 306 is etched using a gas having an etching selectivity substantially the same as the lower electrode 310A and the sacrificial layer 305. For example, the support layer 306 is etched using a gas including O₂ and Ar in addition to the fluorine-based gas. Also, the fluorine-based gas may include CF₄, CHF₃, CH₂F₂, C₄F₆ or C₄F₈. Therefore, only the support layer 306 connected to the upper portions of both neighboring lower electrodes 310A remains. The remaining support layer 306 is shaped such that the remaining support layer 306 is connected in a diamond shape to the four neighboring lower electrodes 310A, as shown in FIG. 2. The remaining support layer 306 is called a support layer 306A.

Referring to FIG. 3E, the second photoresist layer pattern 311 is removed. The second photoresist layer pattern 311 may be removed using oxygen. Referring to FIG. 3F, the sacrificial layer 305 is removed. The sacrificial layer 305 is removed through a dip-out treatment. The dip-out treatment is performed using a material having an etching selectivity substantially the same as the support layer 306A, e.g., HF or Buffered Oxide Etchant (BOE).

As described above, when the sacrificial layer 305 is removed using the material having the etching selectivity substantially the same as the support layer 306A, the support layer 306A is connected to the upper portion of both neighboring lower electrodes 310A thereby reducing leaning of the lower electrode 310A in the dip-out treatment. The sacrificial layer 305 on a bottom of the support layer 306A that is connected to the upper portion of both neighboring lower electrodes 310A is removed and becomes a vacant space 10.

A perspective view of the structure shown in FIG. 3F is illustrated in FIG. 3G. Referring to FIG. 3G, the support layer 306A is connected in a diamond shape to the upper portion of the four neighboring lower electrodes 310A. The sacrificial layer 305 is completely removed after the dip-out treatment. Since the sacrificial layer 305 is removed by being dipped in solution due to the characteristic of the dip-out treatment, the sacrificial layer 305 in the bottom of the support layer 306A is completely removed as shown in FIG. 3G.

Since the support layer 306A may be a nitride layer, which is an insulation material, it is possible to perform a subsequent process without an individual removing process.

A cylinder-shaped capacitor is fabricated by forming a dielectric layer and an upper electrode over the lower electrode 310A.

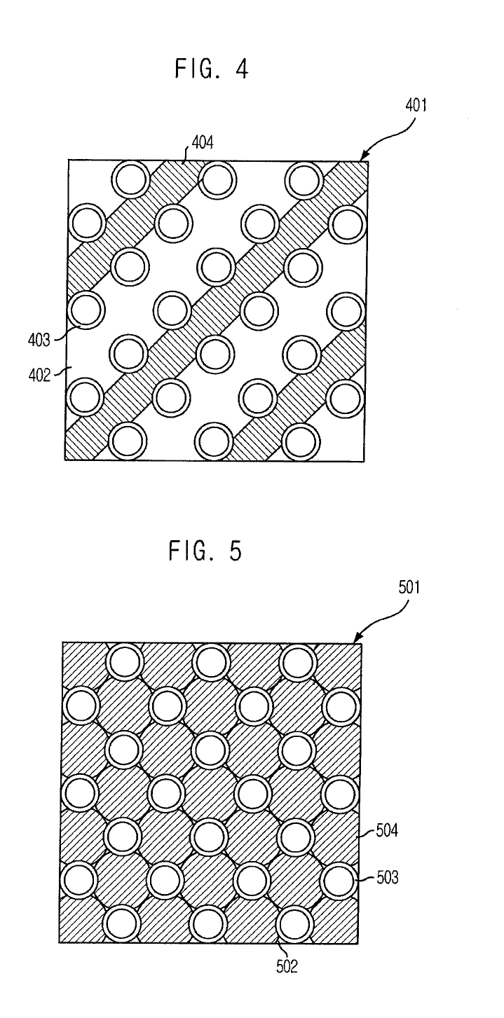

FIG. 4 illustrates a capacitor of the semiconductor device in accordance with a third embodiment of the present invention. Referring to FIG. 4, a sacrificial layer 402 including a plurality of lower electrodes 403 is formed over a substrate 401. A support layer 404 connected to the upper portion of the neighboring lower electrodes 403 is formed in a line-type configuration. The support layer 404 may be a nitride layer.

As described above, leaning of the lower electrodes 403 is reduced in a subsequent dip-out treatment of the sacrificial layer 402 by forming the support layer 404 connected in a diamond shape to the upper portion of the four neighboring lower electrodes 403. Accordingly, a bridge effect between the lower electrodes 403 may be reduced. Since the lower electrode 403 having a small bottom critical dimension (CD) and a large height due to high integration of the semiconductor device is supported by the support layer 404, the leaning of the lower electrodes 403 is reduced in a subsequent dip-out treatment of the sacrificial layer 402.

FIG. 5 illustrates a capacitor fabricating method of the semiconductor device in accordance with a fourth embodiment of the present invention.

Referring to FIG. 5, a sacrificial layer 502 including a plurality of lower electrodes 503 is formed over a substrate 501. A support layer 504 connected to the upper portion of the neighboring lower electrodes 503 is formed in a mesh-type configuration. The support layer 504 may be a nitride layer.

As described above, leaning of the lower electrodes 503 is reduced in the subsequent dip-out treatment of the sacrificial layer 502 by forming the support layer 504 connected to each upper portion of the neighboring four lower electrodes 503. Accordingly, a bridge effect between the lower electrodes 503 may be reduced. In other words, since the lower electrode 503 has a decreasing bottom critical dimension (CD) and has an increasing height supported by the support layer 504 according to the high integration of the semiconductor device, the leaning of the lower electrodes 503 is reduced in a subsequent dip-out treatment of the sacrificial layer 502.

The embodiments of the present invention can reduce leaning of the support layer 306A in the dip-out treatment of the sacrificial layer 305 by forming the lower electrode 310A connected to the upper portion of the neighboring lower electrodes 310A. Therefore, the embodiments of the present invention can also reduce a bridge effect from occurring due to leaning of the lower electrode 310A.

The embodiments of the present invention exemplify performance of the subsequent process without an individual removing process after the dip-out treatment of the sacrificial layer 305 by forming the support layer 306A which has an etching selectivity substantially the same as the sacrificial layer 305 and includes the insulation material, e.g., the nitride layer.

Since the above-mentioned present invention can reduce leaning of the lower electrodes and a bridge effect caused by the leaning of the lower electrodes, the manufacturing time of the semiconductor can be shortened and the throughput can be improved, which is economically advantageous.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a capacitor in a semiconductor device, the method comprising:
forming a sacrificial layer and a support layer over a substrate;
forming a plurality of openings by etching the support layer and the sacrificial layer;
forming an electrode in inner walls of the openings including sidewalls of the support layer patterned through etching;
removing a portion of the patterned support layer; and
removing the sacrificial layer.

2. The method of claim 1, wherein removing the portion of the patterned support layer comprises:
coating a resultant structure including the electrode with a photoresist layer until the openings are filled;
patterning the photoresist layer such that the photoresist layer remains over the support layer connected to neighboring electrodes and inside the openings;
etching the exposed support layer; and
removing the photoresist layer.

3. The method of claim 1, wherein the support layer includes a material having an etching selectivity to one of the sacrificial layer and the electrode.

4. The method of claim 3, wherein the support layer includes a nitride-based layer.

5. The method of claim 4, wherein the support layer has a thickness ranging from approximately 100 Å to 3000 Å.

6. The method of claim 1, wherein forming the openings comprises etching the support layer using a gas including O₂ and Ar in addition to a fluorine-based gas.

7. The method of claim 1, wherein etching the portion of the support layer comprises using a gas including O₂ and Ar in addition to a fluorine-based gas.

8. The method of claim 6, wherein the fluorine-based gas includes one selected from a group consisting of CF₄, C₄F₆, C₄F₈, CHF₃, and CH₂F₂.

9. The method of claim 7, wherein the fluorine-based gas includes one selected from a group consisting of CF₄, C₄F₆, C₄F₈, CHF₃, and CH₂F₂.

10. The method of claim 1, wherein the sacrificial layer includes an oxide-based layer.

11. The method of claim 10, wherein removing the sacrificial layer comprises performing a dip-out treatment.

12. The method of claim 11, wherein performing the dip-out treatment comprises using HF or buffered oxide etchant (BOE).

13. The method of claim 1, wherein the lower electrode includes a material containing titanium nitride (TiN).

14. The method of claim 2, wherein removing the photoresist layer comprises employing a removal process using oxygen.

15. The method of claim 1, wherein forming the electrode comprises:
forming a conductive layer over a resultant surface profile including the openings; and
performing an etch-back process on the conductive layer in a manner to leave the conductive layer in inner walls of the openings including the sidewalls of the support layer patterned through the etching.

16. A method for fabricating a capacitor in a semiconductor device, the method comprising:
forming a sacrificial layer and a support layer over a substrate;
forming a plurality of openings by etching the support layer and the sacrificial layer;
forming an electrode in inner walls of the openings;
removing a portion of the support layer; and
removing the sacrificial layer.

17. The method of claim 16, wherein forming the electrode in the inner walls of the openings comprises forming the electrode in sidewalls of the support layer patterned through etching.

18. The method of claim 16, wherein removing the portion of the support layer comprises:
coating a resultant structure including the electrode with a photoresist layer until the openings are filled;
patterning the photoresist layer such that the photoresist layer remains over the support layer connected to neighboring electrodes and inside the openings;
etching the exposed support layer; and
removing the photoresist layer.

19. The method of claim 16, wherein removing the sacrificial layer comprises performing a dip-out treatment.

20. The method of claim 16, wherein forming the electrode comprises:
forming a conductive layer over a resultant surface profile including the openings; and
performing an etch-back process on the conducive layer in a manner to leave the conductive layer in inner walls of the openings including the sidewalls of the support layer patterned by the etching.

21. The method of claim 16, wherein the support layer includes a material having an etching selectivity to one of the sacrificial layer and the electrode.
